(19) United States
(12) Patent Application Publication
(10) Pub. No.: US 2025/0203892 A1
(43) Pub. Date: Jun. 19, 2025

(54) METAL-INSULATOR-METAL DEVICE STRUCTURES AND METHODS OF FORMING THE SAME

(71) Applicant: TAIWAN SEMICONDUCTOR MANUFACTURING COMPANY, LTD., Hsinchu (TW)

(72) Inventors: Jen-Po LIN, Hsinchu (TW); Hsiao-Kuan WEI, Taoyuan (TW); Man-Yun WU, Hsinchu (TW)

(21) Appl. No.: 18/627,570

(22) Filed: Apr. 5, 2024

Related U.S. Application Data
(60) Provisional application No. 63/610,160, filed on Dec. 14, 2023.

(51) Int. Cl. H01G 4/10; H01L 23/522

(52) U.S. Cl. CPC H10D 1/696; H01G 4/10; H01L 23/5223

(57) ABSTRACT

Embodiments of present disclosure provide a MIM capacitor device structure including a first conductive layer and a dielectric stack disposed on the first and second portions of the first conductive layer. The dielectric stack includes a first dielectric layer disposed on the first conductive layer, a high-k dielectric layer disposed on the first dielectric layer, and a second dielectric layer disposed on the high-k dielectric layer. The structure further includes a second conductive layer disposed on the dielectric stack, a first conductive feature extending through the first conductive layer and a first portion of the dielectric stack, and a second conductive feature extending through a second portion of the dielectric stack and the second conductive layer.

### CROSS-REFERENCE TO RELATED APPLICATIONS

This application claims priority to U.S. Provisional Application Ser. No. 63/610,160 filed on Dec. 14, 2023, which is incorporated by reference in its entirety.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed. In the course of IC evolution, functional density (i.e., the number of interconnected devices per chip area) has generally increased while geometric size (i.e., the smallest component that can be created using a fabrication process) has decreased.

Many of the ICs involve capacitive structures to store a charge in a variety of semiconductor devices. Such capacitive structures include, for example, metal-oxide-semiconductor (MOS) capacitors, p-n junction capacitors, and metal-insulator-metal (MIM) capacitors. MIM capacitors can be used in mixed signal devices and logic devices, such as embedded memories and radio frequency devices. MIM capacitors exhibit improved frequency and temperature characteristics. Furthermore, MIM capacitors are formed in or over the metal interconnect layers, thereby reducing CMOS transistor process integration interactions or complications.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1I are cross-sectional side views of a metal-insulator-metal (MIM) capacitor device structure at various stages of fabrication, in accordance with some embodiments.

FIG. 1E-1 is an enlarged cross-sectional side view of a dielectric stack of the MIM capacitor device structure of FIG. 1E, in accordance with some embodiments.

FIG. 2 illustrates concentrations of various materials in a dielectric stack of the MIM capacitor device structure, in accordance with some embodiments.

FIGS. 3A-3C illustrate concentrations of TiO, F, H in the dielectric stack of the MIM capacitor device structure, in accordance with some embodiments.

FIG. 4 illustrates atomic percentages of various materials in a bottom of a high-k dielectric layer of the MIM capacitor device structure, in accordance with some embodiments.

FIG. 5A illustrates a forward biasing MIM capacitor, in accordance with some embodiments.

FIG. 5B illustrates a forward biasing MIM capacitor, in accordance with some embodiments.

FIG. 6A illustrates a multi-plate MIM capacitor, in accordance with some embodiments.

FIG. 6B is an electrical equivalent circuit of the multi-plate MIM capacitor of FIG. 6A, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Embodiments of present disclosure relate to MIM capacitor device structures and methods of manufacturing the MIM capacitor device structures. Some embodiments provide a MIM capacitor device structure including a dielectric stack formed between two conductive layers. The dielectric stack includes a high-k dielectric layer disposed between two TION layers. The dielectric stack and the methods of forming the same can lead to improved forward biasing time-dependent dielectric breakdown (TDDB) lifetime and reverse biasing TDDB lifetime.

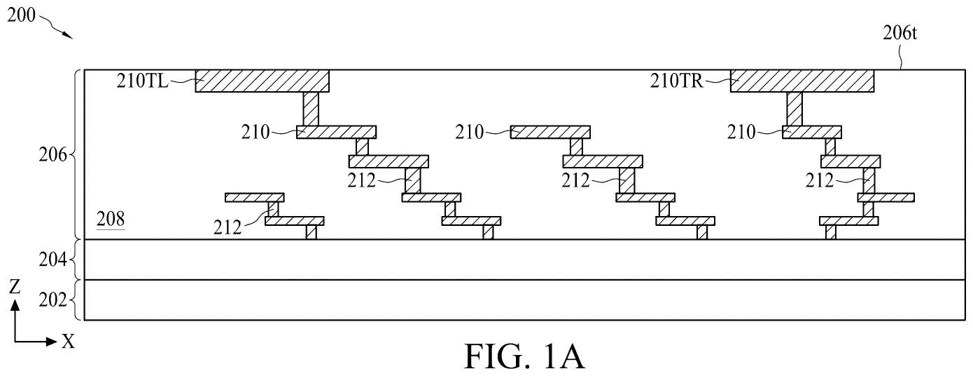

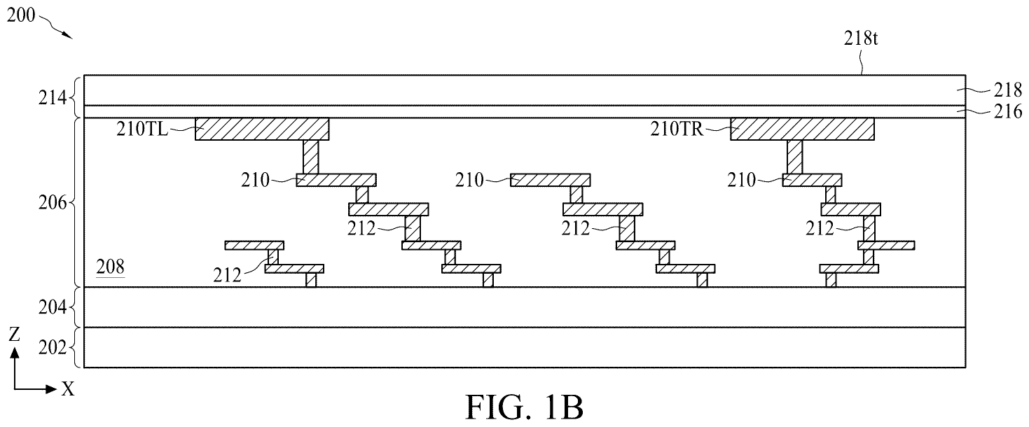

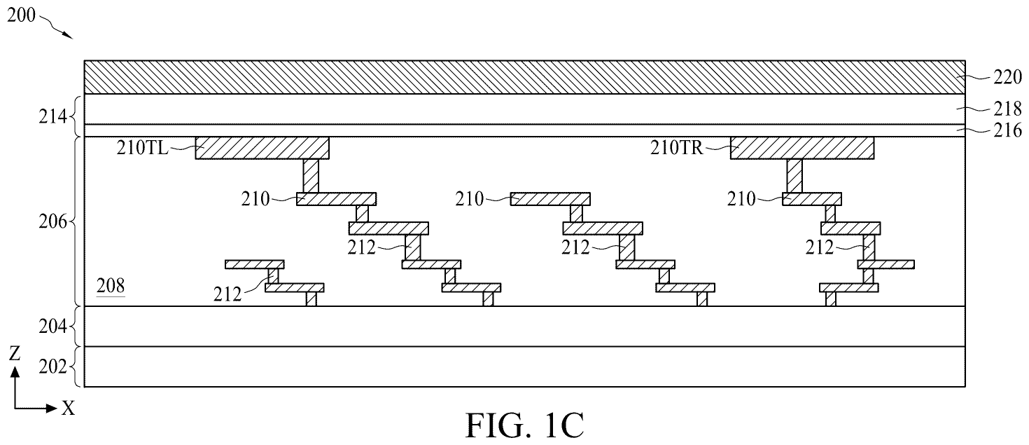

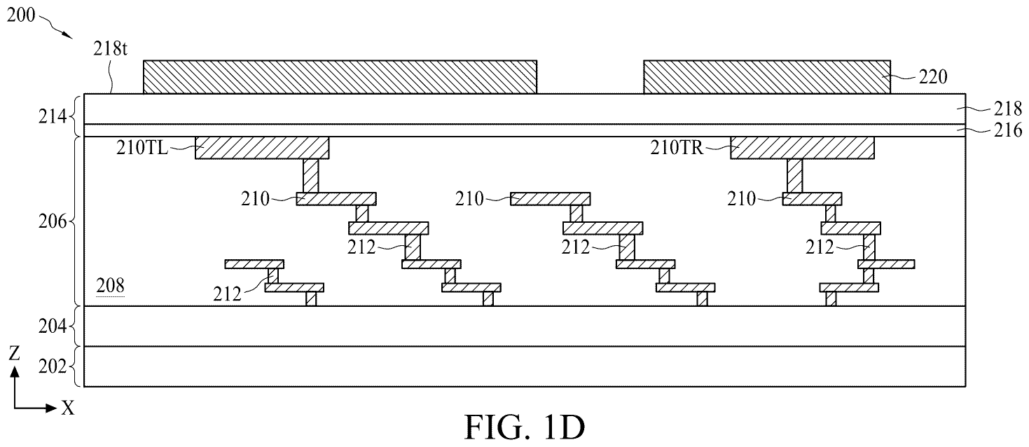

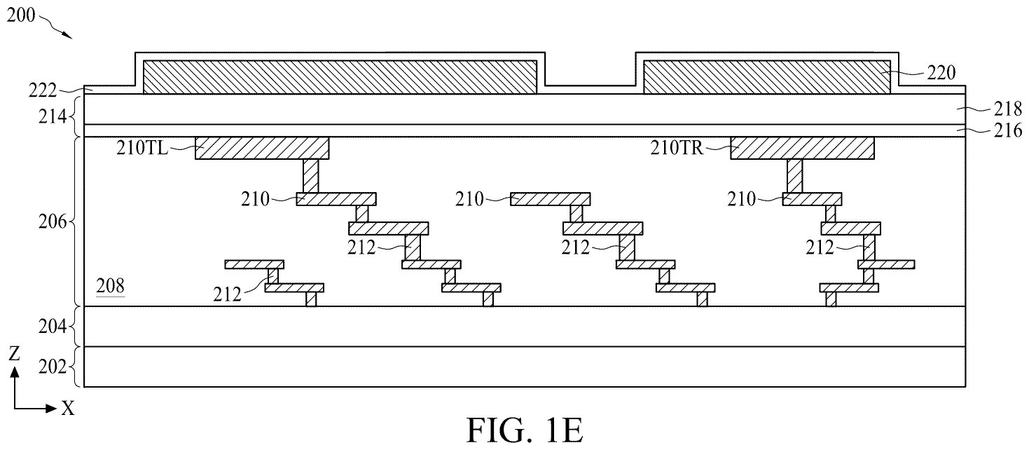

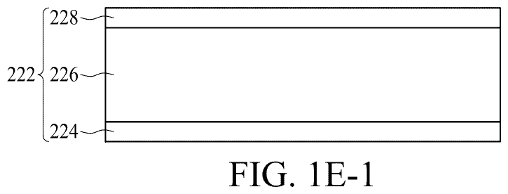

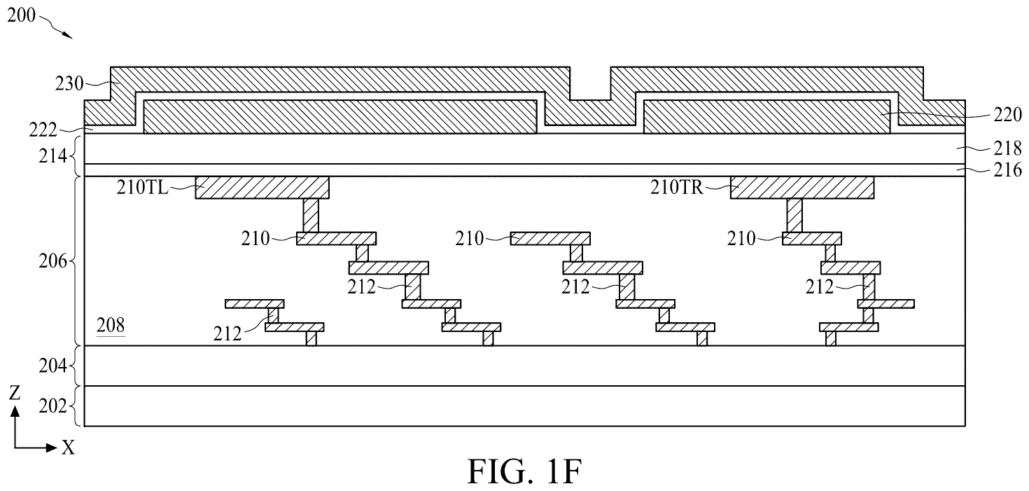

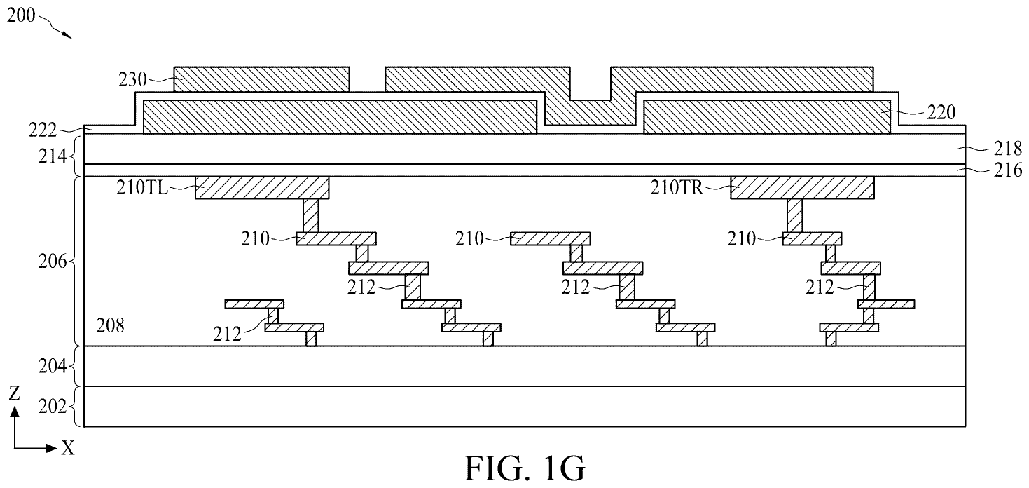

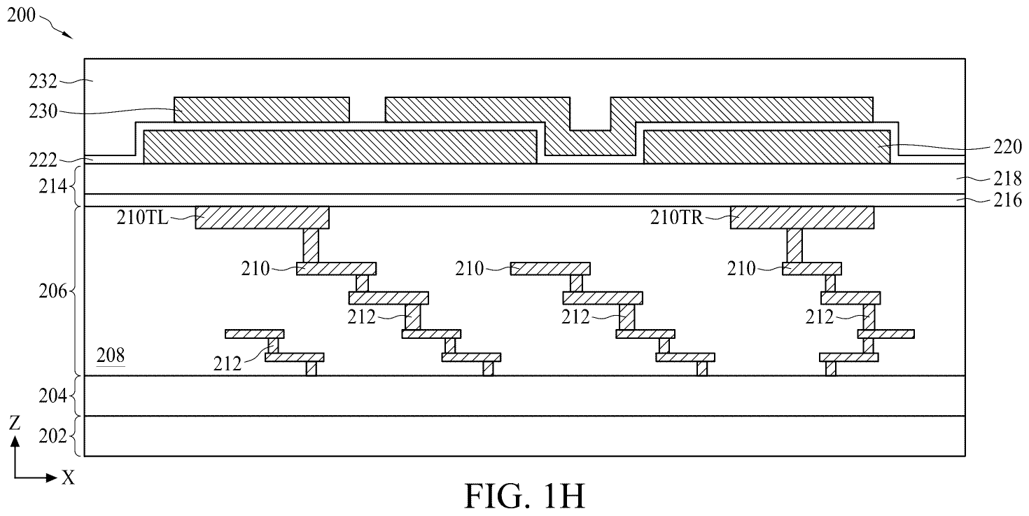

FIGS. 1A-1I are cross-sectional side views of a metal-insulator-metal (MIM) capacitor device structure 200 at various stages of fabrication, in accordance with some embodiments. It is understood that additional operations can be provided before, during, and after processes shown by FIGS. 1A-1I, and some of the operations described below can be replaced or eliminated, for additional embodiments of the method. The order of the operations/processes is not limiting and may be interchangeable.

As shown in FIG. 1A, the MIM capacitor device structure 200 includes a substrate 202, a device layer 204 formed in and/or on a front side of the substrate 202, and an interconnect structure 206 formed over the device layer 204. MIM capacitors may be formed on and within the interconnect structure 206.

In some embodiments, the substrate 202 may be a semiconductor substrate, such as a bulk semiconductor, a semiconductor-on-insulator (SOI) substrate, or the like, which may be doped, for example, with P-type or N-type dopants, or undoped. The substrate 202 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 202 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GalnAs, GalnP, and/or GalnAsP; or combinations thereof. The substrate 202 may further include isolation features (not shown), such as shallow trench isolation (STI) features or local oxidation of silicon (LOCOS) features. Isolation features may surround and isolate various device elements in the device layer 204.

The device layer 204 includes device elements formed in and/or on the substrate 202. Device elements may include transistors, such as metal oxide semiconductor field effect transistors (MOSFET), complementary metal oxide semiconductor (CMOS) transistors, bipolar junction transistors (BJT), high voltage transistors, high frequency transistors, p-channel and/or n channel field effect transistors (PFETs/NFETs), etc., diodes, and/or other applicable elements. In some embodiments, the device elements are formed in the substrate 202 in a front-end-of-line (FEOL) process.

The interconnect structure 206 includes various conductive features, such as a first plurality of conductive features 210 and second plurality of conductive features 212, and an intermetal dielectric (IMD) layer 208 to separate and isolate various conductive features 210, 212. In some embodiments, the first plurality of conductive features 210 are conductive lines and the second plurality of conductive features 212 are conductive vias. The interconnect structure 206 includes multiple levels of the conductive features 210, and the conductive features 210 are arranged in each level to provide electrical paths to various device elements in the device layer 204 disposed below. The conductive features 212 provide vertical electrical routing from the device layer 204 to the conductive features 210 and between conductive features 210. For example, the bottom-most conductive features 212 of the interconnect structure 206 may be electrically connected to the conductive contacts disposed over source/drain regions and gate electrodes of transistors in the device layer 204.

The IMD layer 208 includes one or more dielectric materials to provide isolation functions to various conductive features 210, 212. The IMD layer 208 may include multiple levels embedding multiple levels of conductive features 210, 212. A level of the interconnect structure 206 may be a layer of the IMD layer 208. The layers are sometimes referred to as M1, M2, . . . . M10, M11, et, with M1 being closest to the device layer 204. In some embodiments, the conductive features 210 on the topmost IMD layer are referred to as top metal and denoted as conductive features 210TL, 210TR.

The IMD layer 208 may be made from a dielectric material, such as SiOₓ, SiOₓC_{y}H_{z}, SIOCN, SiON, or SiOₓC_{y}, where x, y and z are integers or non-integers. In some embodiments, the IMD layer 208 includes a low-k dielectric material having a k-value less than that of silicon dioxide. In some embodiments, the IMD layer 208 may include etch stop layers between levels of low-k dielectric material layers to facilitate patterning and formation of the conductive features 210, 212. The etch stop layers may be made of silicon carbide (SIC), silicon nitride (SiₓN_{y}), silicon carbonitride (SiCN), silicon oxycarbide (SiOC), silicon oxycarbon nitride (SiOCN), or another applicable material.

The conductive features 210 and conductive features 212 may be made from one or more electrically conductive materials, such as metal, metal alloy, metal nitride, or silicide. For example, the conductive features 210 and the conductive features 212 are made from copper, aluminum, aluminum copper alloy, titanium, titanium nitride, tantalum, tantalum nitride, titanium silicon nitride, zirconium, gold, silver, cobalt, nickel, tungsten, tungsten nitride, tungsten silicon nitride, platinum, chromium, molybdenum, hafnium, iridium, other suitable conductive material, or a combination thereof. In some embodiments, a barrier layer, not shown, may be formed between the IMD layer 208 and the conductive features 210, 212 to prevent diffusion of the conductive features 210, 212 to the dielectric material in the IMD layer 208. The barrier layer may be made of titanium (Ti), titanium alloy, tantalum (Ta) or tantalum alloy. For example, the barrier layer may be made of tantalum nitride (TaN).

In some embodiments, a planarization process, a chemical mechanical polishing (CMP) process, and/or a cleaning process may be performed to expose the topmost conductive features 210T prior to forming the MIM capacitors. Two topmost conductive features 210TL and 210TR are shown and to connect with electrodes of the capacitors to be formed. As shown in FIG. 1A, the topmost conductive features 210TL and 201TR are exposed on a top surface 206t of the interconnect structure 206.

As shown in FIG. 1B, an insulation layer 214 is formed over the interconnect structure 206. In some embodiments, the insulation layer 214 may include an etch stop layer 216 and a dielectric layer 218 sequentially deposited over the interconnect structure 206. The etch stop layer 216 may include silicon carbide (SiC), silicon nitride (SiₓN_{y}), silicon carbonitride (SiCN), silicon oxycarbide (SiOC), silicon oxycarbon nitride (SiOCN), or another suitable material. In some embodiments, the etch stop layer 216 may be formed by performing a plasma enhanced chemical vapor deposition (CVD) process, a low-pressure CVD process, an atomic layer deposition (ALD) process, or another applicable process.

The dielectric layer 218 may include undoped silicate glass (USG), fluorinated silicate glass (FSG), carbon-doped silicate glass, silicon oxide, silicon nitride or silicon oxynitride. In some embodiments, the dielectric layer 218 may be formed by a chemical vapor deposition (CVD) process, a spin-on process, a sputtering process, or a combination thereof. In some embodiments, the thickness of the dielectric layer 218 is in a range from about 300 nm to about 500 nm. The dielectric layer 218 may have a substantially planar top surface 218t, as shown in FIG. 1B.

As shown in FIG. 1C, a conductive layer 220 is deposited on the top surface 218t of the dielectric layer 218. The conductive layer 220 may be formed from a suitable electrically conductive material. In some embodiments, the conductive layer 220 is formed from titanium nitride (TiN), tantalum nitride (TaN), molybdenum nitride (MoN), or a combination thereof. In some embodiments, the conductive layer 220 may be formed by a physical vapor deposition (PVD) process, a CVD process, or an atomic layer deposition (ALD) process. The conductive layer 220 may have a thickness ranging from about 10 nm to about 100 nm.

As shown in FIG. 1D, the conductive layer 220 may be patterned to form two or more portions (electrodes). Processes such as photolithography process, maskless lithography process, etch process, or variety of processes suitable for transferring a pattern to the conductive layer may be performed. Each portion of the conductive layer 220 may be formed in a variety of shapes in the x-y plane (viewed from top), for example, a circle, a curvilinear shape, a rectangle, a line, a polygon including with rounded corners, and/or other suitable shapes. In some embodiment, the two portions of the conductive layer 220 overlap with the topmost conductive features 210TL, 210TR. One of the two portions of the conductive layer 220 may function as a bottom electrode of an MIM capacitor. After the formation of the portions of the conductive layer 220, a clean process may be performed to remove any etchant remaining in the processing chamber.

As shown in FIG. 1E, a dielectric stack 222 is formed over the dielectric layer 218 and the portions of the conductive layer 220. FIG. 1E-1 is an enlarged cross-sectional side view of the dielectric stack 222. As shown in FIG. 1E-1, the dielectric stack 222 includes a first dielectric layer 224, a high-k dielectric layer 226 formed on the first dielectric layer 224, and a second dielectric layer 228 formed on the high-k dielectric layer 226. The first and second dielectric layers 224, 228 may include any suitable dielectric material. In some embodiments, the first and second dielectric layers 224, 228 each includes TION. It is believed that with the second dielectric layer 228, the MIM capacitor can operate under high temperatures, such as temperatures ranging from about 100 degrees Celsius to about 125 degrees Celsius, without being broken down.

The high-k dielectric layer 226 may function as the insulator of the MIM capacitor. In some embodiments, the high-k dielectric layer 226 includes dielectric materials having a dielectric constant (k) value in a range from about 10 to about 35. The high-k dielectric layer 226 may be oxides of Li, Be, Mg, Ca, Sr, Sc, Y, Zr, Hf, Al, La, Ce, Pr, Nd, Sm, Eu, Gd, Tb, Dy, Ho, Er, Tm, Yb, Lu, or another suitable material. Exemplary high-k dielectric materials for the high-k dielectric layer 226 may include Al₂O₃, ZrO₂, Ta₂O₅, HfO₂, La₂O₃, TiO₂, SiO₂, or a combination hereof. In some embodiments, the high-k dielectric layer 226 includes HfO₂, ZrO₂, or HfₓZr₁₋ₓO₂ (0<x<1). In some embodiments, the high-k dielectric layer 226 is formed by a plasma enhanced chemical vapor deposition (PECVD) process, a low-pressure CVD (LPCVD) process, an atomic layer deposition (ALD) process, a molecular beam deposition (MBD) process, or another suitable process. In some embodiments, the high-k dielectric layer 226 has a thickness less than about 6 nm. In some embodiments, the high-k dielectric layer 226 is a crystalline high-k dielectric material and is deposited by ALD.

The dielectric stack 222 may be formed by different methods and may lead to different properties of the MIM capacitor. In some embodiments, a first method includes a treatment process being performed on the portions of the conductive layer 220 prior to the formation of the first dielectric layer 224. The treatment process may be one or more plasma treatments. In some embodiments, the treatment process utilizes a nitrogen-containing plasma. In some embodiments, the treatment process is an N₂ plasma treatment process, an NH₃ plasma treatment, or a combination thereof. The exposed portions of the dielectric layer 218 may be also treated by the treatment process. After the treatment process, a dielectric layer is deposited on the treated surfaces of the portions of the conductive layer 220 and the treated surfaces of the dielectric layer 218. The dielectric layer reacts with the treated surfaces of the conductive layer 220 and the treated surfaces of the dielectric layer 218 to form the first dielectric layer 224. In some embodiments, the dielectric layer is TiO, and the first dielectric layer 224 is TION. In some embodiments, the dielectric layer has a first thickness ranging from about 4 angstroms to about 6 angstroms. The second dielectric layer 228 may be formed by any suitable process. In some embodiments, the second dielectric layer 228 is formed by depositing a dielectric layer, such as a TiO layer, on the high-k dielectric layer 226, and then forming a conductive layer 230 (FIG. 1F) on the dielectric layer. In some embodiments, the conductive layer 230 includes TiN and is formed by a PVD process. The PVD process can lead to nitridation/re-sputter effect on the dielectric layer to form the second dielectric layer 228. In some embodiments, the second dielectric layer 228 includes TION. The dielectric layer (TiO) for forming the second dielectric layer 228 may have a second thickness greater than the first thickness of the dielectric layer (TiO) for forming the first dielectric layer 224. In some embodiments, the second thickness ranges from about 9 angstroms to about 11 angstroms. In some embodiments, the thickness of the first dielectric layer 224 is substantially greater than the thickness of the second dielectric layer 228. For example, the first dielectric layer 224 has a thickness ranging from about 10 angstroms to about 25 angstroms, while the second dielectric layer 228 has a thickness of a few angstroms. The MIM capacitor with the dielectric stack 222 formed by the first method as described above has a forward biasing TDDB lifetime ranging from about 0.02 years to about 0.22 years and a reverse biasing TDDB lifetime ranging from about 0.0027 years to about 0.0047 years.

In some embodiments, a second method includes the second thickness of the dielectric layer for forming the second dielectric layer 228 being reduced to be the same as the first thickness of the dielectric layer for forming the first dielectric layer 224, and the first dielectric layer 224 is formed by the same process as described above. As a result, the MIM capacitor formed by the second method has a forward biasing TDDB lifetime ranging from about 4.23 years to about 4.43 years and a reverse biasing TDDB lifetime ranging from about 0.0014 years to about 0.0034 years.

In some embodiments, a third method includes the second thickness of the dielectric layer for forming the second dielectric layer 228 being reduced to be the same as the first thickness of the dielectric layer for forming the first dielectric layer 224, and the processes to form the first dielectric layer 224 are changed. For example, the dielectric layer (TiO) is first deposited on the portions of the conductive layer 220 and the dielectric layer 218, and the treatment process is performed on the dielectric layer to form the first dielectric layer 224. With a thinner dielectric layer to form the second dielectric layer 228 and the treatment process being performed after the deposition of the dielectric layer for forming the first dielectric layer 224, the MIM capacitor has a forward biasing TDDB lifetime ranging from about 5.0 years to about 5.2 years and a reverse biasing TDDB lifetime ranging from about 5.18 years to about 5.38 years. The comparisons of the characteristics of the dielectric stack 222 formed by the first, second, and third methods are described below.

As shown in FIG. 1F, the conductive layer 230 is deposited on the dielectric stack 222. The conductive layer 230 may include the same material as the conductive layer 220 and may be deposited by the same process as the conductive layer 220. The conductive layer 230 may have a thickness ranging from about 10 nm to about 100 nm. In some embodiments, the first and second conductive layers 220, 230 each includes TiN. As shown in FIG. 1G, a patterning process is performed on the conductive layer 230 to form two or more portions of the conductive layer 230. The patterning process may be the same patterning process to form portions of the conductive layer 220. One of the portions of the conductive layer 230 may function as a top electrode of the MIM capacitor. In some embodiments, the MIM capacitor includes the conductive layer 220 as the bottom electrode, the dielectric stack 222 as the insulator, the conductive layer 230 as the top electrode, and the MIM capacitor is a symmetric structure with respect to a center line of the high-k dielectric layer 226.

As shown in FIG. 1H, a dielectric layer 232 is deposited on the dielectric stack 222 and the portions of the conductive layer 230. In some embodiments, the dielectric layer 232 may include the same material as the dielectric layer 218 and may be formed by the same process as the dielectric layer 218. In some embodiments, the dielectric layer 232 may include undoped silicate glass (USG), fluorinated silicate glass (FSG), carbon-doped silicate glass, silicon oxide, silicon nitride or silicon oxynitride. In some embodiments, the dielectric layer 232 may be formed by a chemical vapor deposition (CVD) process, a spin-on process, a sputtering process, or a combination thereof. In some embodiments, the thickness of the dielectric layer 232 is in a range from about 300 nm to about 500 nm.

As shown in FIG. 1I, conductive features 234L, 234R are formed through the portions of the conductive layer 230, the dielectric stack 222, the portions of the conductive layer 220, and the insulation layer 214. In some embodiments, the conductive feature 234L is electrically connected to the conductive feature 210TL, and the conductive feature 234R is electrically connected to the conductive feature 210TR, as shown in FIG. 1I. The conductive features 234L, 234R each may include copper, aluminum, AlCu, and/or other suitable materials. In some embodiments, barrier layers, not shown, may be deposited in openings prior to forming the conductive features 234L, 234R, and the conductive features 234L, 234R are formed on the barrier layers. In some embodiments, the portion of the conductive layer 220 electrically connected to the conductive feature 234L is the bottom electrode of the MIM capacitor, the high-k dielectric layer 226 is the insulator of the MIM capacitor, and the portion of the conductive layer 230 electrically connected to the conductive feature 234R is the top electrode of the MIM capacitor. The conductive features 234L, 234R provide electrical connections to the MIM capacitor.

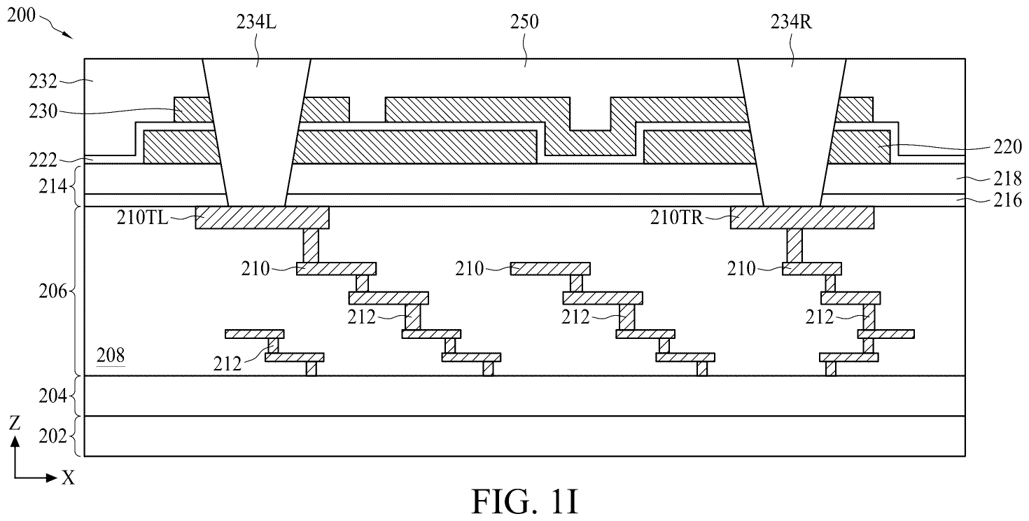

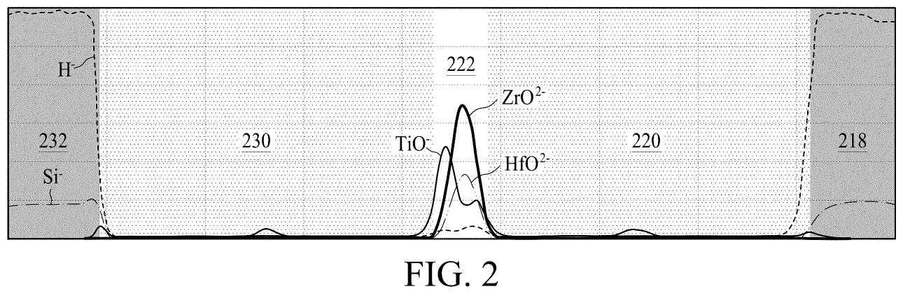

FIG. 2 illustrates concentrations of various materials in the dielectric stack 222 of the MIM capacitor device structure 200, in accordance with some embodiments. In some embodiments, as shown in FIG. 2, the dielectric stack 222 includes two TiO concentration peaks, indicating the existence of the first and second dielectric layers 224, 228.

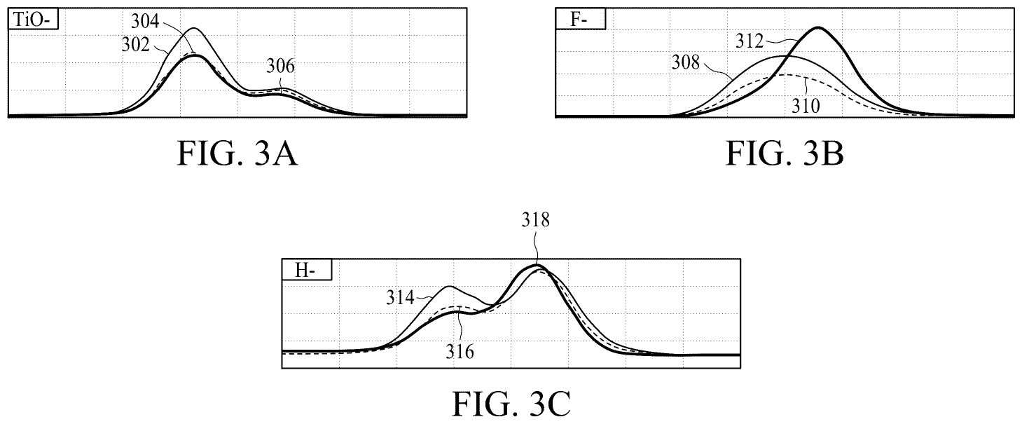

FIGS. 3A-3C illustrates concentrations of TiO, F, H in the dielectric stack 222 of the MIM capacitor device structure 200, in accordance with some embodiments. As shown in FIG. 3A, in some embodiments, TiO concentration profile 302 is a result of forming the dielectric stack 222 by a first method, which is performing the treatment process prior to depositing the dielectric layer (TiO), and the second thickness of the second dielectric layer 228 being substantially greater than the first thickness of the first dielectric layer 224. In some embodiments, TiO concentration profile 304 is a result of forming the dielectric stack 222 by a second method, which is performing the treatment process prior to depositing the dielectric layer (TiO), and the second thickness of the second dielectric layer 228 being substantially the same as the first thickness of the first dielectric layer 224. In some embodiments, TiO concentration profile 306 is a result of forming the dielectric stack 222 by a third method, which is performing the treatment process after depositing the dielectric layer (TiO), and the second thickness of the second dielectric layer 228 being substantially the same as the first thickness of the first dielectric layer 224.

As shown in FIG. 3B, in some embodiments, F concentration profile 308 is a result of forming the dielectric stack 222 by the first method, F concentration profile 310 is a result of forming the dielectric stack 222 by the second method, and F concentration profile 312 is a result of forming the dielectric stack 222 by the third method. As shown in FIG. 3C, in some embodiments, H concentration profile 314 is a result of forming the dielectric stack 222 by the first method, H concentration profile 316 is a result of forming the dielectric stack 222 by the second method, and H concentration profile 318 is a result of forming the dielectric stack 222 by the third method.

As described above, the MIM capacitor formed by the first method has a forward biasing TDDB lifetime ranging from about 0.02 years to about 0.22 years and a reverse biasing TDDB lifetime ranging from about 0.0027 years to about 0.0047 years, the MIM capacitor formed by the second method has a forward biasing TDDB lifetime ranging from about 4.23 years to about 4.43 years and a reverse biasing TDDB lifetime ranging from about 0.0014 years to about 0.0034 years, and the MIM capacitor formed by the third method has a forward biasing TDDB lifetime ranging from about 5.0 years to about 5.2 years and a reverse biasing TDDB lifetime ranging from about 5.18 years to about 5.38 years. Thus, in some embodiments, even though the dielectric stack 222 is a tri-layer structure (the first dielectric layer 224, the high-k dielectric layer 226, and the second dielectric layer 228), the property of the MIM capacitor may be different with different methods to form the dielectric stack 222. Without being bound by a particular theory, it is believed that higher concentrations of F and H located at the interface between the high-k dielectric layer 226 and the first dielectric layer 224 lead to improved forward biasing and reverse biasing TDDB lifetimes. The source of F and H may be the deposition chamber for depositing the dielectric layer (TiO) and/or treatment chamber for performing the treatment process. F and H may be used to clean the deposition chamber and/or the treatment chamber. As a result, residue F and H from the interior chamber surface may be incorporated in the MIM capacitor device structure 200. In some embodiments, the third method is performed, and more F and H are incorporated into the MIM capacitor device structure 200 as a result of performing the treatment process after the deposition process.

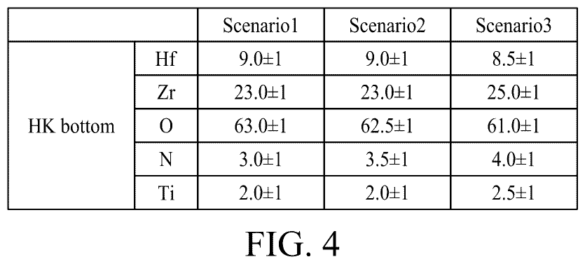

FIG. 4 illustrates atomic percentages of various materials in a bottom of the high-k dielectric layer 226 of the MIM capacitor device structure 200, in accordance with some embodiments. As shown in FIG. 4, numbers under scenario 1 are the results of the first method, numbers under scenario 2 are the results of the second method, and numbers under scenario 3 are the results of the third method. The concentration of oxygen in the bottom of the high-k dielectric layer 226 formed by the third method is substantially less than the concentration of oxygen in the bottom of the high-k dielectric layer 226 formed by the first or the second method. The difference ranges from about 1.5 atomic percent to about 2 atomic percent. In some embodiments, the oxygen concentration located at the top of the high-k dielectric layer 226 is greater than the oxygen concentration located at the bottom of the high-k dielectric layer 226 as a result of the third method. For example, a ratio of the bottom oxygen concentration to the top oxygen concentration is less than 1, such as from about 0.91 to about 0.99. Without being bound by a particular theory, it is believed that the lower oxygen concentration from the third method is a result of the treatment process being performed after the deposition of the dielectric layer (TiO). The treatment process forms a nitrogen-rich surface of the first dielectric layer 224. In some embodiments, the high-k dielectric layer 226 is formed by an ALD process. The first precursor may be a metal-containing precursor, such as a Zr-containing or Hf-containing precursor. The metal-containing precursor has a greater affinity for the nitrogen-rich surface. As a result, more metal-containing precursor molecules are adsorbed on the surface of the first dielectric layer 224 compared to the processes of the first and second methods. The second precursor of the ALD process to form the high-k dielectric layer 226 may be an oxygen-containing precursor. Due to the limited space, non-stoichiometric oxidation state of the metal-containing precursor may occur. In other words, oxygen deficiency leads to oxygen-vacancies in the high-k dielectric layer 226, such as at the bottom of the high-k dielectric layer 226. As described in FIGS. 3A to 3C, there is a high concentration of the F and H piled up at the interface between the high-k dielectric layer 226 and the first dielectric layer 224, which is a result of F and H filling the oxygen-vacancies. In some embodiments, nitrogen from the first dielectric layer 224 (as a result of the treatment process) may diffuse into the high-k dielectric layer 226 to fill the oxygen-vacancies. As shown in FIG. 4, the nitrogen concentration under scenario 3 is substantially higher than those under scenarios 1 and 2. In some embodiments, under scenario 3, the nitrogen concentration located at the bottom of the high-k dielectric layer 226 is greater than the nitrogen concentration located at the top of the high-k dielectric layer 226. For example, a ratio of the bottom nitrogen concentration to the top nitrogen concentration is greater than 1, such as from about 2 to about 5. However, the difference in the nitrogen concentrations does not make up for the difference in the oxygen concentrations when comparing the three scenarios. It is believed that F and H fill the oxygen-vacancies not filled by nitrogen under scenario 3. One of the reasons that the third method improved both forward biasing TDDB lifetime and reverse biasing TDDB lifetime may be that the N, F, and H passivated oxygen-vacancies in the high-k dielectric layer 226 lead to improved electrical properties of the high-k dielectric layer 226. Furthermore, the MIM capacitor device structure 200 formed by the third method includes the MIM capacitor having a forward capacitance ranging from about 50.82 fF/μm² to about 52.82 fF/μm² and a reverse capacitance ranging from about 50.19 fF/μm² to about 52.19 fF/μm².

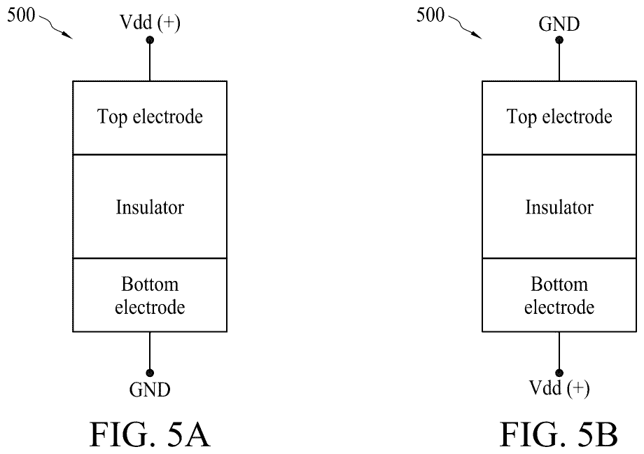

FIG. 5A illustrates a forward biasing MIM capacitor, in accordance with some embodiments, and FIG. 5B illustrates a forward biasing MIM capacitor, in accordance with some embodiments. As shown in FIG. 5A, a MIM capacitor 500 includes a bottom electrode, an insulator disposed over the bottom electrode, and a top electrode disposed over the insulator. In some embodiments, the bottom electrode is the conductive layer 220 (FIG. 1I), the insulator is the dielectric stack 222 (FIG. 1I), and the top electrode is the conductive layer 230 (FIG. 1I). In a forward biasing circuit, the bottom electrode is connected to the ground (GND), and the top electrode is connected to a positive voltage (Vdd). In some embodiments, the conductive feature 234L (FIG. 1I) is connected to the GND, and the conductive feature 234R is connected to the Vdd.

As shown in FIG. 5B, the bottom electrode is connected to the Vdd, and the top electrode is connected to the GND. As a result, the MIM capacitor 500 shown in FIG. 5B is reverse biased.

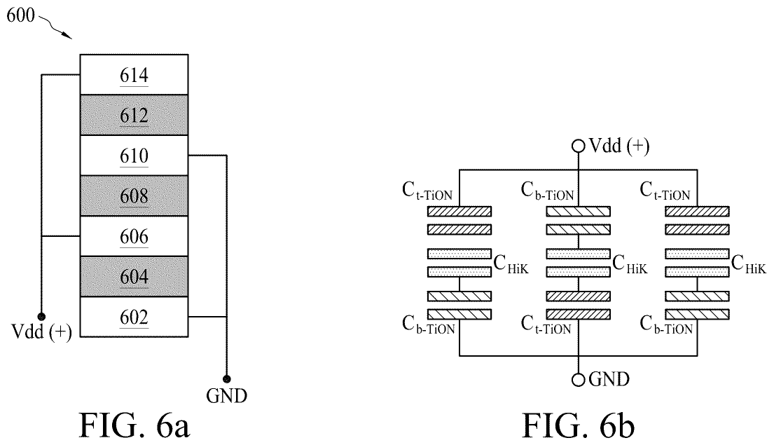

FIG. 6A illustrates a multi-plate MIM capacitor 600, in accordance with some embodiments. As shown in FIG. 6A, the multi-plate MIM capacitor 600 includes a first electrode 602, a first dielectric stack 604 disposed over the first electrode 602, a second electrode 606 disposed over the first dielectric stack 604, a second dielectric stack 608 disposed over the second electrode 606, a third electrode 610 disposed over the second dielectric stack 608, a third dielectric stack 612 disposed over the third electrode 610, and a fourth electrode 614 disposed over the third dielectric stack 612. In some embodiments, the first, second, third, and fourth electrodes 602, 606, 610, 614 include the same material as the conductive layer 220, and the first, second, and third dielectric stacks 604, 608, 612 include the same materials as the dielectric stack 222. In some embodiments, the dielectric stacks 604, 608, 612 are formed by the third method described above. FIG. 6B is an electrical equivalent circuit of the multi-plate MIM capacitor of FIG. 6A, in accordance with some embodiments.

Various embodiments or examples described herein offer multiple advantages over the state-of-art technology. In some embodiments, a dielectric stack 222 is disposed between two electrodes of the MIM capacitor. The dielectric stack 222 includes a high-k dielectric layer 226 disposed between first and second dielectric layers 224, 228. The three-layer dielectric stack 222 leads to the MIM capacitor operatable at higher temperatures. Furthermore, by performing the treatment process after depositing the dielectric layer (TiO), the forward biasing TDDB lifetime and the reverse biasing TDDB lifetime are improved.

An embodiment is a MIM capacitor device structure. The structure includes a first conductive layer having a first portion and a second portion and a dielectric stack disposed on the first and second portions of the first conductive layer. The dielectric stack includes a first dielectric layer disposed on the first and second portions of the first conductive layer, a high-k dielectric layer disposed on the first dielectric layer, and a second dielectric layer disposed on the high-k dielectric layer. The structure further includes a second conductive layer disposed on the dielectric stack, and the second conductive layer includes a first portion and a second portion. The structure further includes a first conductive feature extending through the first portion of the first conductive layer, a first portion of the dielectric stack, and the first portion of the second conductive layer and a second conductive feature extending through the second portion of the first conductive layer, a second portion of the dielectric stack, and the second portion of the second conductive layer.

Another embodiment is a method. The method includes depositing a first conductive layer over a substrate, patterning the first conductive layer to form first and second portions of the first conductive layer, and forming a dielectric stack on the first and second portions of the first conductive layer. The forming the dielectric stack includes depositing a first dielectric layer, performing a treatment process, depositing a high-k dielectric layer on the first dielectric layer, and depositing a second dielectric layer on the high-k dielectric layer. The method further includes depositing a second conductive layer on the dielectric stack and patterning the second conductive layer to form first and second portions of the second conductive layer.

A further embodiment is a method. The method includes depositing a first conductive layer over a substrate and forming a dielectric stack on the first conductive layer. The forming the dielectric stack includes depositing a first dielectric layer, performing a nitridation process on the first dielectric layer to form a nitride layer, and depositing a high-k dielectric layer on the nitride layer. The high-k dielectric layer has a first oxygen concentration located at a top of the high-k dielectric layer substantially greater than a second oxygen concentration located at a bottom of the high-k dielectric layer. The forming the dielectric stack further includes depositing a second dielectric layer on the high-k dielectric layer. The method further includes depositing a second conductive layer on the dielectric stack.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A structure, comprising:
a first conductive layer comprising a first portion and a second portion;
a dielectric stack disposed on the first and second portions of the first conductive layer, wherein the dielectric stack comprises:
a first dielectric layer disposed on the first and second portions of the first conductive layer;
a high-k dielectric layer disposed on the first dielectric layer; and
a second dielectric layer disposed on the high-k dielectric layer;
a second conductive layer disposed on the dielectric stack, wherein the second conductive layer comprises a first portion and a second portion;
a first conductive feature extending through the first portion of the first conductive layer, a first portion of the dielectric stack, and the first portion of the second conductive layer; and
a second conductive feature extending through the second portion of the first conductive layer, a second portion of the dielectric stack, and the second portion of the second conductive layer.

2. The structure of claim 1, wherein the first and second dielectric layers each comprises TION.

3. The structure of claim 2, wherein the first and second dielectric layers have different thicknesses.

4. The structure of claim 2, wherein the first and second conductive layers each comprises TiN.

5. The structure of claim 1, wherein the high-k dielectric layer has a top oxygen concentration and a bottom oxygen concentration, wherein the top oxygen concentration is substantially greater than the bottom oxygen concentration.

6. The structure of claim 5, wherein a ratio of the bottom oxygen concentration to the top oxygen concentration ranges from about 0.91 to about 0.99.

7. The structure of claim 1, wherein the high-k dielectric layer has a top nitrogen concentration and a bottom nitrogen concentration, wherein the bottom nitrogen concentration is substantially greater than the top nitrogen concentration.

8. The structure of claim 7, wherein a ratio of the bottom nitrogen concentration to the top nitrogen concentration ranges from about 2 to about 5.

9. A method, comprising:
depositing a first conductive layer over a substrate;
patterning the first conductive layer to form first and second portions of the first conductive layer;
forming a dielectric stack on the first and second portions of the first conductive layer, comprising:
depositing a first dielectric layer;
performing a treatment process;
depositing a high-k dielectric layer on the first dielectric layer; and
depositing a second dielectric layer on the high-k dielectric layer;
depositing a second conductive layer on the dielectric stack; and
patterning the second conductive layer to form first and second portions of the second conductive layer.

10. The method of claim 9, wherein the treatment process is performed before the depositing of the first dielectric layer.

11. The method of claim 9, wherein the treatment process is performed before the depositing of the first dielectric layer.

12. The method of claim 11, wherein the treatment process is a plasma nitridation process.

13. The method of claim 11, wherein the treatment process is an N₂ plasma treatment process, an NH₃ plasma treatment, or a combination thereof.

14. The method of claim 11, wherein the high-k dielectric layer is deposited by atomic layer deposition.

15. The method of claim 14, wherein oxygen-vacancies are formed at a bottom of the high-k dielectric layer.

16. The method of claim 15, further comprising filling the oxygen-vacancies with F, H, and N.

17. A method, comprising:
depositing a first conductive layer over a substrate;
forming a dielectric stack on the first conductive layer, comprising:
depositing a first dielectric layer;
performing a nitridation process on the first dielectric layer to form a nitride layer;
depositing a high-k dielectric layer on the nitride layer, wherein the high-k dielectric layer has a first oxygen concentration located at a top of the high-k dielectric layer substantially greater than a second oxygen concentration located at a bottom of the high-k dielectric layer; and
depositing a second dielectric layer on the high-k dielectric layer; and
depositing a second conductive layer on the dielectric stack.

18. The method of claim 17, further comprising forming a first conductive feature through the first conductive layer and a first portion of the dielectric stack and forming a second conductive feature through the second conductive layer and a second portion of the dielectric stack.

19. The method of claim 17, wherein the first dielectric layer comprises TiO, the nitride layer comprises TiON, and the second dielectric layer comprises TION.

20. The method of claim 17, wherein the high-k dielectric layer is deposited by atomic layer deposition.
